(19) United States
(12) Patent Application Publication
(10) Pub. No.: US 2009/0166848 A1
(43) Pub. Date: Jul. 2, 2009

(54) Method for Enhancing the Adhesion of a Passivation Layer on a Semiconductor Device

(76) Inventors: Volker Berghof, Dresden (DE); Thorsten Schedel, Dresden (DE)

Correspondence Address: SLATER & MATSIL, L.L.P., 17950 PRESTON ROAD, SUITE 1000, DALLAS, TX, 75252, US

(21) Appl. No.: 11/967,165

(22) Filed: Dec. 29, 2007

(51) Int. Cl. H01L 23/12; H01L 21/44

(52) U.S. Cl. 257/700; 438/612; 257/E21.575; 257/E23.168

(57) ABSTRACT

In a method for making a semiconductor component, an integrated circuit is provided with a chip pad on an active side. A conductive track is connected to the chip pad and a passivation layer covers the conductive track. Forming the conductive track includes structuring an uneven sidewall for form closure with the passivation layer.

### TECHNICAL FIELD

The present invention relates generally to semiconductor devices and in particular embodiments to a method for enhancing the adhesion of a passivation layer on a semiconductor device.

### BACKGROUND

In many redistribution layer processes, the rerouting traces (i.e., the conductive tracks formed in the redistribution layer) are covered with a gold layer for corrosion protection. For mechanical and corrosion protection these traces have to be covered with a surface passivation layer which may be made, for instance, of an organic permanent resist. The redistribution layer on semiconductor devices usually comprises a seed layer, a layer of copper on said seed layer, a nickel layer arranged thereon, and a gold layer covering the latter. The production of the redistribution layer, which realizes an electrical connection between active structures and an associated bonding pad, requires a photolithographic process. In an exemplary method, the wafer is at first coated with a photoresist which subsequently is exposed and developed, and then coated with a metal layer, after which the photoresist is stripped. These process steps may be performed once or repeatedly, as the case may be, until the desired layer sequence is achieved.

In a method described in the applicant's U.S. Pat. No. 7,115,496, which is incorporated herein by reference, the necessary patterning of the gold layer is realized by means of a customary lithographic process. After the deposition of a seed layer and a copper/nickel layer situated thereon of the redistribution layer, the gold is deposited on the entire redistribution layer. The nickel layer serves as an adhesion layer for the copper layer and the latter in turn serves as an adhesion layer for the gold covering layer. Since the gold layer itself cannot oxidize, it serves, on the one hand, as a secure adhesion layer for a solder material, in order for example to connect a 3D structure to a connection pad of a printed circuit board, which is usually composed of copper, and, on the other hand, as a protective layer for the copper layer situated underneath. In other words, the copper layer is largely protected from corrosion by the gold layer, at least from above.

If the side edges of the conductive tracks of the redistribution layer are not protected against corrosion and oxidation then the possibly laterally penetrating corrosion or advancing oxidation may ultimately lead locally to a destruction of the redistribution layer, thereby limiting the service life of the electronic component provided with such a redistribution layer. This problem is often solved by encapsulating the redistribution layer. The wafer provided with the redistribution layer is covered on its entire surface with an organic protective layer, which protects the redistribution layer from corrosion and oxidation in that it produces a dense covering of the metal surface of the redistribution layer through chemical and/or mechanical bonding.

### SUMMARY OF THE INVENTION

In one embodiment, an integrated circuit includes a semiconductor substrate including active components formed in an upper surface thereof. A number of metallization layers overlie the semiconductor substrate and interconnect the active components. A redistribution line overlies the final metallization layer and is insulated therefrom. The redistribution line includes a plurality of conductive tracks, each of the conductive tracks extending between a contact pad and an external connection pad. Each conductive track has a sidewall that includes an upper portion that overhangs a lower portion. A passivation layer overlies an upper surface and the upper and lower sidewall portions of each conductive track of the redistribution layer.

### BRIEF DESCRIPTION OF THE DRAWINGS

Figures are provided for a better understanding of the present disclosure, wherein exemplary embodiments of semiconductor products are shown which can be made by using the described methods.

FIG. 1 is a schematic drawing of a cross sectional view of a semiconductor wafer with a conductive track having generally vertical, stepped side walls;

FIG. 2 is a schematic drawing of a cross sectional view of a semiconductor wafer with a conductive track having generally outwardly inclined, stepped side walls;

FIG. 3 is a schematic drawing of a cross sectional view of a semiconductor wafer with a conductive track having generally inwardly inclined side walls with a pattern of horizontal grooves; and

FIG. 4 is a schematic drawing of a cross sectional view of a semiconductor wafer with a conductive track having side walls with a single horizontal groove.

### DETAILED DESCRIPTION OF ILLUSTRATIVE EMBODIMENTS

Disclosed herein is a method for making a semiconductor device with enhanced adhesion between the redistribution layer on a semiconductor wafer or a semiconductor chip (commonly referred to as semiconductor device hereinafter) and a passivation layer deposited on top of the redistribution layer.

Many surface passivation materials have poor adhesion properties with regard to metal, especially gold, layers. Therefore, peeling off of these layers during stress test is a high risk. Embodiments of the present invention are disclosed herein to offer ways to increase the adhesion of such passivation layers.

In one aspect, the adhesion between a conductive track located on a surface of a semiconductor device and a passivation layer covering the conductive track is enhanced. A conductive track is formed on the surface of an integrated circuit. The conductive track is subsequently covered with a passivation layer material. Prior to covering the conductive track, the side walls of the conductive track are given a structure that permits the passivation layer material to cling to the side wall due to positive locking. Since the passivation layer not only covers the conductive tracks, but also the free surface areas of the integrated circuit between the conductive tracks, the material of the passivation layer flows over and around the conductive tracks during the covering process, and subsequently clings to the side walls of the conductive tracks with the effect of enhanced adhesion after curing of the passivation material with regard to forces which may otherwise lead to peeling off of the passivation layer.

To give the side walls of the conductive track a structure that permits the passivation layer material to cling to the side wall, an undercut in a side wall of a conductive track may be formed. For example, the undercut can be formed by cutting away material from the lower part of the side wall of an object so as to leave an overhanging portion of the upper part of the side wall of the object in relief, i.e. protruding over the removed lower portion of the object. In the preferred embodiment, the object is the conductive track.

As an example, forming an undercut may comprise forming the side walls with an outward inclination such that the base of the conductive track is narrower than its top surface. This may be achieved by using non-perpendicular light during lithography, i.e. light waves which do not hit the surface of the integrated circuit perpendicularly. Thus, the lower part of a conductive track is narrower than its upper part, such that the inclination of the side walls extending from the relatively narrow lower part to the relatively broad upper part prevents the passivation layer from peeling off.

Another approach to giving the side walls of the conductive track a structure that permits the passivation layer material to cling to the side wall is to underetch the upper part of a conductive track, i.e. to etch away some material from the lower portions of the side walls so as to make them narrower than the upper portions. This approach results in a stepped side wall structure, wherein a lower step of a conductive track is narrower than an adjacent step of the conductive track positioned on top of the lower step. Also in this case, the stepped structure of the side walls extending from the relatively narrow lower part to the relatively broad upper part of the conductive track prevents the passivation layer from peeling off.

It should be understood that both approaches described above may be combined in the making of a single conductive track. For example, a side wall may have a stepped structure and one or more steps may have an inclined side wall portion. For instance, in a semiconductor product, a conductive track may be fabricated to have inclined side walls wherein the base of the conductive track is narrower than its top surface and subsequently, the lower portions of the inclined side wall may be underetched in order to divide the side wall into two or more steps of which the upper step overhangs the lower step.

Yet another approach is to form a horizontal groove or a pattern of horizontal grooves in the side wall of a conductive track. This approach gives the side walls of the conductive track a structure which permits the passivation layer material to cling to the side wall due to positive locking, regardless of whether the base of the conductive track is broader, or equal to, or narrower than the top surface. The reason for this behavior is that the horizontal groove, or pattern of horizontal grooves, respectively, forms an undercut in a side wall of a conductive track to which the passivation layer material can cling, thus enhancing the adhesion between the conductive track and the passivation layer. So, even if the side walls that comprise the groove or grooves have a generally inward inclination, i.e., the top surface is narrower than the base of the conductive track, the grooves still hold the passivation layer in place and prevent it from peeling off.

A single horizontal groove in the side wall of a conductive track may for instance be formed by using defocused light during photolithography. A pattern of horizontal grooves may be formed using a standing light wave during photolithography, whereby the angle of the light waves with regard to the surface of the integrated circuit may be chosen to either form a generally inwardly inclined side wall, or a generally vertical side wall, or a generally outwardly inclined side wall.

A number of these embodiments will now be described with respect to the figures. In each of the drawings, a semiconductor substrate 1, e.g. a wafer, has a conductive track disposed on its upper surface. In this particular example, the conductive tracks are composed of three layers of different materials. A copper conductive layer 2 forms the base of the conductive track. A nickel adhesion layer 3 is formed on top of the copper conductive layer 2 and a gold cover layer 4 is formed on top of the nickel adhesion layer 3.

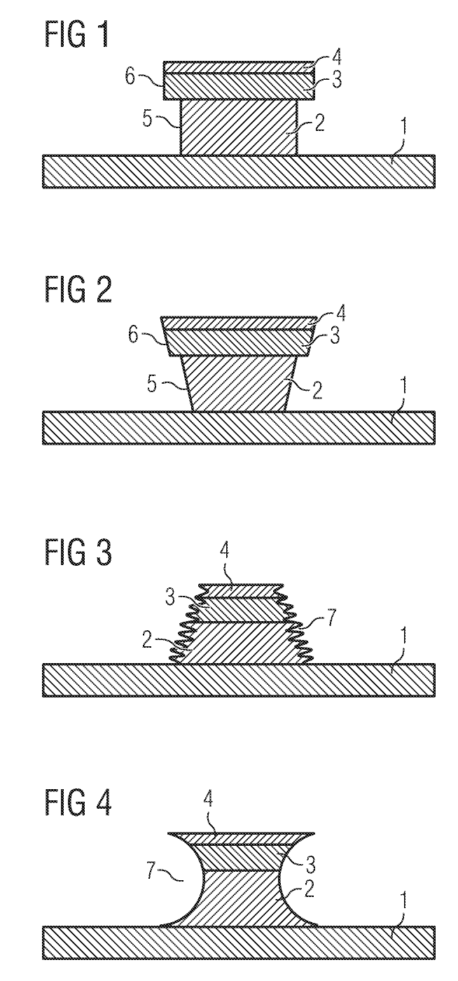

In FIG. 1, the side walls of the conductive track are generally vertical. In an underetching process, material has selectively been removed from the copper layer 2 so that the lower portion 5 of the side wall forms an undercut and the upper portion 6 of the side wall protrudes over the lower portion 5. In other words, the side wall has a stepped structure, with the lower portion 5 forming a first step and the upper portion forming a second step of the side wall.

In the embodiment shown in FIG. 2, the side walls of the conductive track are generally outwardly inclined. As in the previous embodiment, material has selectively been removed from the copper layer 2 in an underetching process so that the lower portion 5 of the side wall forms an undercut and the upper portion 6 of the side wall protrudes over the lower portion 5. Thus, the side wall has been given a stepped structure, with the lower portion 5 forming a first step and the upper portion forming a second step of the side wall.

Another embodiment is shown in FIG. 3, where the side walls of the conductive track are generally inwardly inclined. A pattern of grooves 7 is formed in the side walls. The shape of the side walls corresponds to the waveform of the standing light wave used during lithography. Each of the grooves 7 forms an undercut which helps prevent the passivation layer from peeling off.

In the embodiment of FIG. 4, the conductive track has concave side walls. The concave shape provides a single groove 7, which has been made by using defocused light during photolithography and which forms an undercut to which the passivation layer will cling by positive locking, thereby preventing the passivation layer from peeling off.

What is claimed is:

1. A method for making a semiconductor component, the method comprising:
providing an integrated circuit with a chip pad on an active side thereof;
forming a conductive track over the active side of the integrated circuit, the conductive track connected to the chip pad, the conductive track including a non-planar sidewall; and
forming a passivation layer covering the conductive track, the passivation layer abutting the non-planar sidewall.

2. The method of claim 1, wherein forming the conductive track comprises forming an undercut in a side wall of a conductive track.

3. The method of claim 2, wherein forming an undercut comprises forming the side walls with an outward inclination such that the base of the conductive track is smaller than its top surface.

4. The method of claim 3, wherein the side walls are formed with an outward inclination by using non-perpendicular light during photolithography.

5. The method of claim 2, wherein forming an undercut comprises removing material from a lower portion of a side wall such that an upper portion of the side wall overhangs the lower portion.

6. The method of claim 5, wherein removing material from the lower portion comprises underetching the upper portion of the side wall.

7. The method of claim 2, wherein forming an undercut comprises forming at least one horizontal groove in the side wall of a conductive track.

8. The method of claim 7, wherein forming a horizontal groove comprises using defocused light during photolithography.

9. The method of claim 7, wherein a pattern of horizontal grooves is formed by using a standing light wave during photolithography.

10. The method of claim 1, wherein providing the integrated circuit comprises fabricating the integrated circuit.

11. A method for making a semiconductor component, the method comprising:
providing an integrated circuit with a chip pad on an active side;
forming a conductive track connected to the chip pad; and
forming a passivation layer covering the conductive track, wherein forming the conductive track comprises structuring an uneven sidewall for form closure with the passivation layer.

12. An integrated circuit comprising:
a semiconductor substrate including active components formed in an upper surface thereof;
a plurality of metallization layers overlying the semiconductor substrate and interconnecting the active components, the plurality of metallization layers including a final metallization layer;
a redistribution overlying the final metallization layer and insulated therefrom, the redistribution line including a plurality of conductive tracks, each of the conductive tracks extending between a contact pad and an external connection pad, each conductive track having a sidewall that includes an upper portion that overhangs a lower portion; and
a passivation layer overlying an upper surface and the upper and lower sidewall portions of each conductive track of the redistribution layer.

13. The integrated circuit of claim 12, wherein each conductive track has a sidewall that includes at least one groove.

14. The integrated circuit of claim 13, wherein each conductive track has a sidewall that includes a plurality of grooves.

15. The integrated circuit of claim 14, wherein an angle between the sidewall and the upper surface of the substrate is greater than 90°.

16. The integrated circuit of claim 12, wherein each conductive track has a sidewall that includes a step.

17. The integrated circuit of claim 16, wherein, for each sidewall, the lower portion is parallel to the upper portion.

18. The integrated circuit of claim 16, wherein, for each sidewall, the lower portion is not parallel to the upper portion.

19. The integrated circuit of claim 12, wherein an angle between the lower portion of the sidewall and the upper surface of the substrate is less than 90°.

20. The integrated circuit of claim 12, wherein an angle between the lower portion of the sidewall and the upper surface of the substrate is greater than 90°.

21. The integrated circuit of claim 12, wherein an angle between the lower portion of the sidewall and the upper surface of the substrate is substantially equal to 90°.
